(19) United States
(12) Patent Application Publication
(10) Pub. No.: US 2023/0378050 A1
(43) Pub. Date: Nov. 23, 2023

(54) SEMICONDUCTOR DEVICE AND METHOD OF MANUFACTURING THE SAME

(71) Applicant: RENESAS ELECTRONICS CORPORATION, Tokyo (JP)

(72) Inventor: Takeshi NAKURA, Tokyo (JP)

(21) Appl. No.: 18/188,089

(22) Filed: Mar. 22, 2023

(30) Foreign Application Priority Data
May 19, 2022 (JP) 2022-082154

(51) Int. Cl. H01L 23/522

(52) U.S. Cl. CPC H01L 23/5223; H01L 28/92

(57) ABSTRACT

A semiconductor device includes a first electrode and a second electrode configuring a MIM capacitor. The first electrode includes a first via plug extending along a first direction. The second electrode includes a second lower wiring extending along the first direction and arranged side by side with the first via plug in a second direction. A length of the first via plug in the first direction is larger than a length of the first via plug in the second direction. A length of the second lower wiring in the first direction is larger than a length of the second lower wiring in the second direction. A length of the first via plug in a third direction is larger than a length of the second lower wiring in the third direction.

### CROSS-REFERENCE TO RELATED APPLICATIONS

The disclosure of Japanese Patent Application No. 2022-082154 filed on May 19, 2022, including the specification, drawings and abstract is incorporated herein by reference in its entirety.

### BACKGROUND

The present disclosure relates to a semiconductor device and a method of manufacturing the same.

There are disclosed techniques listed below.
[Patent Document 1] Japanese Unexamined Patent Application Publication No. 2016-171337
Patent Document 1 discloses a semiconductor device in which two electrodes of MIM (Metal Insulator Metal) capacitor are each formed in one wiring layer.

### SUMMARY

In the above semiconductor device, the capacitance value of MIM capacitor is limited by the smallest interval between wirings included in one wiring layer. From a different point of view, in the above semiconductor device, the miniaturization of MIM capacitor is limited by the smallest interval between wirings included in one wiring layer.

Other objects and novel features will become apparent from the description of this specification and the accompanying drawings.

A capacitive element according to the present disclosure includes a first electrode and a second electrode that configure a capacitor. The first electrode includes a first via plug extending along a first direction in plan view. The second electrode includes a first wiring extending along the first direction in plan view and arranged side by side with the first via plug in a second direction orthogonal to the first direction.

According to the present disclosure, it is possible to provide a semiconductor device in which at least one of the capacitance value and the miniaturization of MIM capacitor is not limited by the smallest interval between wirings included in one wiring layer.

### BRIEF DESCRIPTION OF THE DRAWINGS

FIG. 1 is a plan view showing a semiconductor device according to a first embodiment.

FIG. 2 is a perspective view showing a MIM capacitor according to the first embodiment.

FIG. 3 is a cross-sectional view showing the MIM capacitor according to the first embodiment.

FIG. 4 is a cross-sectional view viewed from the line segment IV-IV in FIG. 3.

FIG. 5 is a cross-sectional view viewed from the line segment V-V in FIG. 3.

FIG. 6 is a cross-sectional view viewed from the line segment VI-VI in FIG. 3.

FIG. 7 is a cross-sectional view viewed from the line segment VII-VII in FIG. 3.

FIG. 8 is a cross-sectional view showing a step of manufacturing method of the semiconductor device according to the first embodiment.

FIG. 9 is a cross-sectional view showing a step after the step shown in FIG. 8 in the manufacturing method of the semiconductor device according to the first embodiment.

FIG. 10 is a cross-sectional view showing a step after the step shown in FIG. 9 in the manufacturing method of the semiconductor device according to the first embodiment.

FIG. 11 is a cross-sectional view showing a step after the step shown in FIG. 10 in the manufacturing method of the semiconductor device according to the first embodiment.

FIG. 12 is a cross-sectional view showing a step after the step shown in FIG. 11 in the manufacturing method of the semiconductor device according to the first embodiment.

FIG. 13 is a cross-sectional view showing a step after the step shown in FIG. 12 in the manufacturing method of the semiconductor device according to the first embodiment.

FIG. 14 is a cross-sectional view showing a step after the step shown in FIG. 13 in the manufacturing method of the semiconductor device according to the first embodiment.

FIG. 15 is a cross-sectional view showing a MIM capacitor according to a comparative example.

FIG. 16 is a cross-sectional view showing a MIM capacitor according to a second embodiment.

FIG. 17 is a cross-sectional view showing a step of manufacturing method of the semiconductor device according to the second embodiment.

FIG. 18 is a cross-sectional view showing a step after the step shown in FIG. 17 in the manufacturing method of the semiconductor device according to the second embodiment.

FIG. 19 is a cross-sectional view showing a step after the step shown in FIG. 18 in the manufacturing method of the semiconductor device according to the second embodiment.

FIG. 20 is a cross-sectional view showing a step after the step shown in FIG. 19 in the manufacturing method of the semiconductor device according to the second embodiment.

FIG. 21 is a cross-sectional view showing a step after the step shown in FIG. 20 in the manufacturing method of the semiconductor device according to the second embodiment.

### DETAILED DESCRIPTION

Hereinafter, embodiments will be described with reference to the drawings. In the following drawings, the same or corresponding parts are denoted by the same reference numerals, and the description thereof will not be repeated. Hereinafter, for convenience of explanation, a first direction X, a second direction Y, and a third direction Z orthogonal to one another are used.

When the terms “orthogonal,” “along,” “congruent,” “equivalent,” and the like are used in the present embodiment to represent relative relationships such as geometric sentences and relative relationships such as position, magnitude, and direction, the terms allow for manufacturing errors or slight variations.

### First Embodiment

Configuration of Semiconductor Device

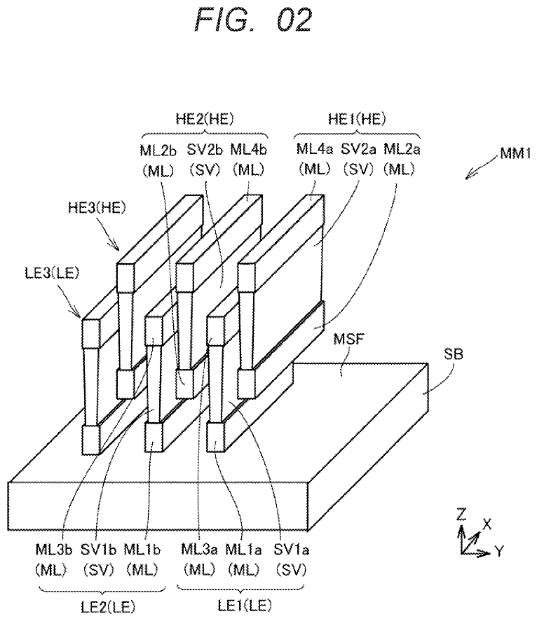

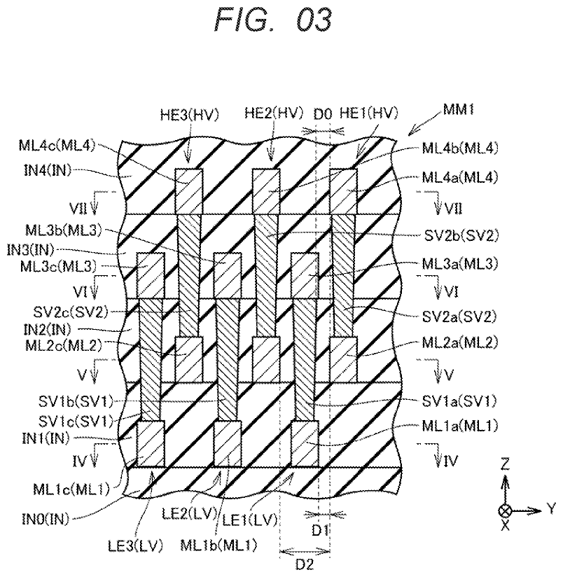

A semiconductor device SD according to the first embodiment is, for example, a microcomputer. The semiconductor device SD is, for example, in chip state and has a semiconductor substrate SUB (refer to FIG. 2). The semiconductor substrate SUB has a main surface SMF extending along the first direction X and the second direction Y and orthogonal to the third direction Z. Forming regions such as a flash memory FM, a flash memory driving circuit FD, SRAM circuit SM, an analog circuit AL, and a logic circuit LC are arranged on the main surface SMF of the semiconductor substrate SUB. The flash memory driving circuit FD and the analog circuit AL include a MIM capacitor MM1 (refer to FIGS. 2 and 3).

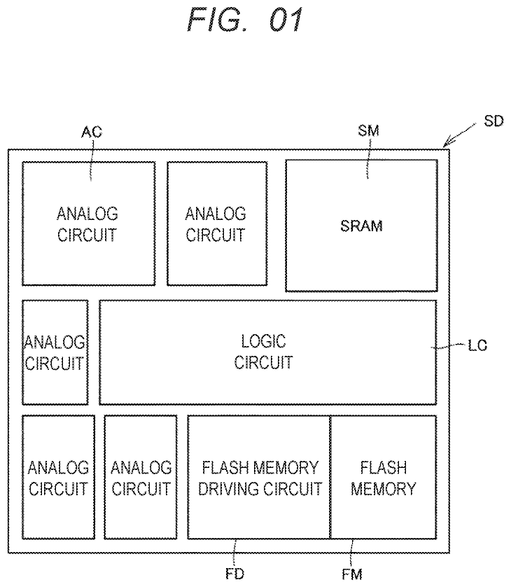

The semiconductor device SD of the present embodiment is not limited to a semiconductor chip, and may be in a wafer state prior to being divided into semiconductor chips, or may be in a packaged state in which the semiconductor chip is sealed with a sealing resin. The circuit arrangement shown in FIG. 1 is an example, and is not limited thereto. In the present specification, the term “plan view” means a viewpoint viewed from the third direction Z orthogonal to the main surface SMF of the semiconductor substrate SB (FIG. 2). In the present specification, the term “lower” means a side closer to the semiconductor substrate SB than the comparative object in the third direction Z, and the term “upper” means the opposite side.

Configuration of MIM Capacitor

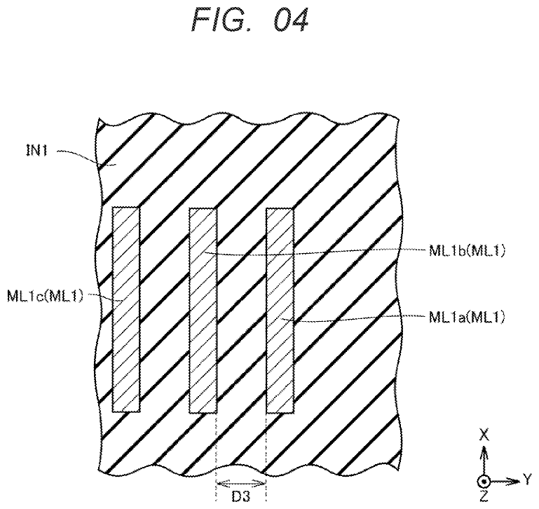

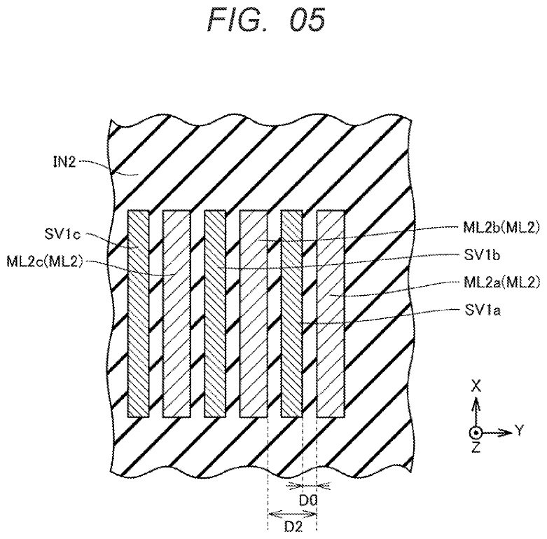

As shown in FIG. 2, the MIM capacitor MM1 is formed on the main surface SMF of the semiconductor substrate SUB having the main surface SMF. The MIM capacitor MM1 is configured by a plurality of first electrodes LE, a plurality of second electrodes HE, and a dielectric film IN (refer to FIG. 3). The plurality of first electrodes LE are connected in parallel to each other, for example. Each of the plurality of first electrodes LE is connected to a first lead-out wiring LL (refer to FIG. 5). The plurality of second electrodes HE are connected in parallel to each other, for example. Each of the plurality of second electrodes HE is connected to a second lead-out wiring HL (refer to FIG. 6).

As shown in FIG. 2, each of the plurality of first electrodes LE and the plurality of second electrodes HE extends along the first direction X. Each of the plurality of first electrodes LE and each of the plurality of second electrodes HE are alternately arranged side by side and spaced apart in the second direction Y orthogonal to the first direction X. From a different viewpoint, the MIM capacitor MM1 includes a plurality of sets of the first electrode LE and the second electrode HE facing each other.

The capacitance value of MIM capacitor MM1 is determined by the area of the region facing in the second direction Y in the first electrode LE and the second electrode HE of each set, the distance between the first electrode LE and the second electrode HE of each set in the second direction Y, and the dielectric constant of the dielectric film IN that separates between the first electrode LE1 and the second electrode HE1 of each set.

As shown in FIGS. 2 and 3, each of the plurality of first electrodes LE has, for example, a configuration equivalent to each other. Each of the plurality of second electrodes HE has, for example, a configuration equivalent to each other. A lower part of each of the plurality of first electrodes LE is arranged below a lower part of each of the plurality of second electrodes HE. An upper part of each of the plurality of second electrodes HE is arranged above an upper part of each of the plurality of first electrodes LE. An upper part of each of the plurality of first electrodes LE is arranged opposite to a lower part of each of the plurality of second electrodes HE in the second direction Y.

As shown in FIGS. 2 and 3, each of the plurality of first electrodes LE and the plurality of second electrodes HE is configured by, for example, a plurality of wirings ML and a plurality of via plugs SV. Each of the plurality of wirings ML and the plurality of via plugs SV extends along the first direction X. A length of the plurality of wirings ML in the first direction X is larger than a length (width) of each of the plurality of wirings ML in the second direction Y and a length (thickness) of each of the plurality of wirings ML in the third direction Z. A length of each of the plurality of via plugs SV in the first direction X is larger than a length (width) of each of the plurality of via plugs SV in the second direction Y. The length of each of the plurality of via plugs SV in the first direction X is larger than a length (depth) of each of the plurality of via plugs SV in the third direction Z. Each of the plurality of via plugs SV is formed by, for example, filling a slit-shaped via hole with a conductive material. The length of each of the plurality of via plugs SV in the first direction X is larger than the largest dimension of the contact via plugs for electrically connecting between different wiring layers in the semiconductor device SD in plan view, for example.

The material configuring the plurality of first electrodes LE and the plurality of second electrodes HE may be any material having conductivity, but includes at least one selected from the group consisting of aluminum (Al), copper (Cu), and titanium (Ti), for example. Each of the plurality of first electrodes LE and the plurality of second electrodes HE may be formed of a stack of conductive films. The material configuring the plurality of via plugs SV may be any material having conductivity, and includes, for example, Cu or tungsten (W).

The material configuring each of an interlayer dielectric film IN0, a first interlayer dielectric film IN1, a second interlayer dielectric film IN2, a third interlayer dielectric film IN3, and a fourth interlayer dielectric film IN4 may be any material having a dielectric constant high than that of the material configuring the plurality of first electrodes LE and the plurality of second electrodes HE, but includes, for example, silicon dioxide (SiO₂).

As shown in FIGS. 2 and 3, the MIM capacitor MM1 includes, for example, a first electrode LE1, a first electrode LE2, a first electrode LE3, a second electrode HE1, a second electrode HE2, and a second electrode HE3. The second electrode HE1, the first electrode LE1, the second electrode HE2, the first electrode LE2, the second electrode HE3, and the first electrode LE3 are arranged side by side and spaced apart from each other in the second direction Y. A dielectric film IN is arranged between the first electrode LE and the second electrode HE next to each other in the second direction Y. The dielectric film IN includes a stack of a plurality of interlayer dielectric films. The dielectric film IN includes, for example, the interlayer dielectric film IN0, the first interlayer dielectric film IN1, the second interlayer dielectric film IN2 (first dielectric layer), the third interlayer dielectric film IN3 (second dielectric layer), and the fourth interlayer dielectric film IN4, which are sequentially stacked in the third direction Z. The dielectric film IN may include a passivation film instead of the fourth interlayer dielectric film IN4 or on the fourth interlayer dielectric film IN4.

As shown in FIG. 3, the first electrode LE1 includes a first lower wiring ML1a, a first via plug SV1a, and a first upper wiring ML3a. The first lower wiring ML1a, the first via plug SV1a, and the first upper wiring ML3a are arranged in this order in the third direction Z, and are electrically connected to one another.

As shown in FIG. 3, the second electrode HE1 includes a second lower wiring ML2a (first wiring), a second via plug SV2a, and a second upper wiring ML4a. The second lower wiring ML2a (first wiring), the second via plug SV2a, and the second upper wiring ML4a are arranged in this order in the third direction Z, and are electrically connected to one another.

As shown in FIG. 3, the first electrode LE2 includes a third lower wiring ML1b, a third via plug SV1b, and a third upper wiring ML3b. The third lower wiring ML1b, the third via plug SV1b, and the third upper wiring ML3b are arranged in this order in the third direction Z, and are electrically connected to one another.

As shown in FIG. 3, the second electrode HE2 includes a fourth lower wiring ML2b (second wiring), a fourth via plug SV2b, and a fourth upper wiring ML4b. The fourth lower wiring ML2b (second wiring), the fourth via plug SV2b, and the fourth upper wiring ML4b are arranged in this order in the third direction Z, and are electrically connected to one another.

As shown in FIG. 3, the first electrode LE3 includes a fifth lower wiring ML1c, a fifth via plug SV1c, and a fifth upper wiring ML3c. The fifth lower wiring ML1c, the fifth via plug SV1c, and the fifth upper wiring ML3c are arranged in this order in the third direction Z, and are electrically connected to one another.

As shown in FIG. 3, the second electrode HE3 includes a sixth lower wiring ML2c, a sixth via plug SV2c, and a sixth upper wiring ML4c. The sixth lower wiring ML2c, the sixth via plug SV2c, and the sixth upper wiring ML4c are arranged in this order in the third direction Z, and are electrically connected to one another.

As shown in FIG. 3, the first lower wiring ML1a, the third lower wiring ML1b, and the fifth lower wiring ML1c are arranged side by side in the first interlayer dielectric film IN1 so as to be spaced apart from each other in the second direction Y. The first lower wiring ML1a, the third lower wiring ML1b, and the fifth lower wiring ML1c are included in the first wiring layers ML1. The first wiring layers ML1 are formed by patterning one conductive film. The first wiring layers ML1 are formed on the interlayer dielectric film IN0, for example. The first interlayer dielectric film IN1 is formed on the interlayer dielectric film IN0 and the first wiring layers ML1.

As shown in FIG. 3, the second lower wiring ML2a, the first via plug SV1a, the fourth lower wiring ML2b, the third via plug SV1b, the sixth lower wiring ML2c, and the fifth via plug SV1c are arranged side by side in the second interlayer dielectric film IN2 so as to be spaced apart from each other in the second direction Y. The second lower wiring ML2a, the fourth lower wiring ML2b, and the sixth lower wiring ML2c are included in the second wiring layers ML2. The second wiring layers ML2 are formed by patterning one conductive film. The second wiring layers ML2 are formed on the first interlayer dielectric film IN1. The second interlayer dielectric film IN2 is formed on the first interlayer dielectric film IN1 and the second wiring layers ML2.

As shown in FIG. 3, the fourth lower wiring ML2b is arranged between the first lower wiring ML1a and the third lower wiring ML1b in the second direction Y. The shortest distance between the second lower wiring ML2a and the first lower wiring ML1a in the second direction Y is smaller than the shortest distance D1 between the second lower wiring ML2b and the fourth lower D2. The shortest distance D1 is set in accordance with the alignment accuracy of the mask used in photolithography when forming the second wiring layers ML2 in the manufacturing method of semiconductor device SD. The shortest distance D2 may be equal to the smallest distance of the line-and-space pattern defined in design standard of semiconductor device SD. Since the alignment error (alignment accuracy) of the photolithography can be made smaller than the minimum distance of the line-and-space, even if the shortest distance D2 is the minimum distance of the line-and-space, the shortest distance D1 can be made smaller than the shortest distance D2.

As shown in FIG. 3, the first via plug SV1a is formed between the second lower wiring ML2a and the fourth lower wiring ML2b in the second direction Y. The third via plug SV1b is formed between the fourth lower wiring ML2b and the sixth lower wiring ML2c in the second direction Y. The fifth via plug SV1c is formed opposite to the third via plug SV1b with respect to the sixth lower wiring ML2c in the second direction Y. Each of the first via plug SV1a, the third via plug SV1b, and the fifth via plug SV1c penetrates the second interlayer dielectric film IN2 and reaches the first interlayer dielectric film IN1. The first via plug SV1a is connected to the first lower wiring ML1a. The third via plug SV1b is connected to the third lower wiring ML1b. The fifth via plug SV1c is connected to the fifth lower wiring ML1c.

As shown in FIG. 3, the second via plug SV2a, the first upper wiring ML3a, the fourth via plug SV2b, the third upper wiring ML3b, the sixth via plug SV2c, and the fifth upper wiring ML3c are arranged side by side in the third interlayer dielectric film IN3 so as to be spaced apart from each other in the second direction Y. The first upper wiring ML3a, the third upper wiring ML3b, and the fifth upper wiring ML3c are included in the third wiring layers ML3. The third wiring layers ML3 are formed by patterning one conductive film. The third wiring layers ML3 are formed on the second interlayer dielectric film IN2. The third interlayer dielectric film IN3 is formed on the third wiring layers ML3 and the second interlayer dielectric film IN2.

As shown in FIG. 3, the second upper wiring ML4a, the fourth upper wiring ML4b, and the sixth upper wiring ML4c are arranged side by side in the fourth interlayer dielectric film IN4 so as to be spaced apart from each other in the second direction Y. The second upper wiring ML4a, the fourth upper wiring ML4b, and the sixth upper wiring ML4c are included in the fourth wiring layers ML4. The fourth wiring layers ML4 are formed by patterning one conductive film. The fourth wiring layers ML4 are formed on the third interlayer dielectric film IN3. The fourth interlayer dielectric film IN4 is formed on the fourth wiring layers ML4 and the third interlayer dielectric film IN3.

As shown in FIG. 4, a length of each of the first lower wiring ML1a, the third lower wiring ML1b, and the fifth lower wiring ML1c in the first direction X is larger than a length of each of the first lower wiring ML1a, the third lower wiring ML1b, and the fifth lower wiring ML1c in the second direction Y. The lengths of the first lower wiring ML1a, the third lower wiring ML1b, and the fifth lower wiring ML1c in the first direction X are, for example, equal to each other. The arrangement of the first lower wiring ML1a, the third lower wiring ML1b, and the fifth lower wiring ML1c in the second direction Y is, for example, periodic. For example, the shortest distance D3 between the first lower wiring ML1a and the third lower wiring ML1b is equal to the shortest distance between the third lower wiring ML1b and the fifth lower wiring ML1c. The shortest distance D3 between the first lower wiring ML1a and the third lower wiring ML1b is, for example, the smallest distance between wirings included in the first wiring layers ML1. The shortest distance D3 may be equal to the smallest distance of the line-and-space pattern defined in design standard of semiconductor device SD, for example.

As shown in FIG. 5, a length of each of the second lower wiring ML2a, the fourth lower wiring ML2b, and the sixth lower wiring ML2c in the first direction X is larger than a length of each of the second lower wiring ML2a, the fourth lower wiring ML2b, and the sixth lower wiring ML2c in the second direction Y. The lengths of the second lower wiring ML2a, the fourth lower wiring ML2b, and the sixth lower wiring ML2c in the first direction X are, for example, equal to each other. The arrangement of the second lower wiring ML2a, the fourth lower wiring ML2b and the sixth lower wiring ML2c in the second direction Y is, for example, periodic. The shortest distance D2 between the second lower wiring ML2a and the fourth lower wiring ML2b is equal to, for example, the shortest distance between the fourth lower wiring ML2b and the sixth lower wiring ML2c. The shortest distance D2 between the second lower wiring ML2a and the fourth lower wiring ML2b is, for example, the smallest distance between wirings included in the second wiring layers ML2. The shortest distance D2 between the second lower wiring ML2a and the fourth lower wiring ML2b is, for example, equal to the shortest distance D3 between the first lower wiring ML1a and the third lower wiring ML1b.

As shown in FIG. 5, a length of each of the first via plug SV1a, the third via plug SV1b, and the fifth via plug SV1c in the first direction X is larger than a length of each of the first via plug SV1a, the third via plug SV1b, and the fifth via plug SV1c in the second direction Y. The length of each of the first via plug SV1a, the third via plug SV1b, and the fifth via plug SV1c in the second direction Y is equal to or smaller than the length of each of the first lower wiring ML1a, the third lower wiring ML1b, and the fifth lower wiring ML1c in the second direction Y. The length of each of the first via plug SV1a, the third via plug SV1b, and the fifth via plug SV1c in the second direction Y is equal to or smaller than the length of each of the second lower wiring ML2a, the fourth lower wiring ML2b, and the sixth lower wiring ML2c in the second direction Y.

As shown in FIG. 5, the shortest distance DO between the first via plug SV1a and the second lower wiring ML2a is smaller than the shortest distance D2 between the second lower wiring ML2a and the fourth lower wiring ML2b. The shortest distance DO between the first via plug SV1a and the second lower wiring ML2a is smaller than half of the shortest distance D2 between the second lower wiring ML2a and the fourth lower wiring ML2b. For example, the shortest distance DO between the first via plug SV1a and the second lower wiring ML2a is equal to the shortest distance between the first via plug SV1a and the fourth lower wiring ML2b.

The shortest distance DO between the first via plug SV1a and the second lower wiring ML2a is, for example, 0.13 μm or less. Preferably, the shortest distance DO is less than 0.13 μm. More preferably, the shortest distance DO is 0.10 μm or less. The shortest distance DO may be, for example, 0.065 μm.

The shortest distance between the third via plug SV1b and the fourth lower wiring ML2b, the shortest distance between the third via plug SV1b and the sixth lower wiring ML2c, and the shortest distance between the fifth via plug SV1c and the sixth lower wiring ML2c are, for example, equal to the shortest distance DO between the first via plug SV1a and the second lower wiring ML2a.

As shown in FIG. 6, a length of each of the first upper wiring ML3a, the third upper wiring ML3b, and the fifth upper wiring ML3c in the first direction X is larger than a length of each of the first upper wiring ML3a, the third upper wiring ML3b, and the fifth upper wiring ML3c in the second direction Y. The lengths of the first upper wiring ML3a, the third upper wiring ML3b, and the fifth upper wiring ML3c in the first direction X are, for example, equal to each other. The arrangement of the first upper wiring ML3a, the third upper wiring ML3b and the fifth upper wiring ML3c in the second direction Y is, for example, periodic. The shortest distance D5 between the first upper wiring ML3a and the third upper wiring ML3b is, for example, equal to the shortest distance between the third upper wiring ML3b and the fifth upper wiring ML3c. The shortest distance D5 between the first upper wiring ML3a and the third upper wiring ML3b is, for example, the smallest distance between wirings included in the third wiring layers ML3. The shortest distance D5 between the first upper wiring ML3a and the third upper wiring ML3b is equal to, for example, the shortest distance D2 between the second lower wiring ML2a and the fourth lower wiring ML2b and the shortest distance D3 between the first lower wiring ML1a and the third lower wiring ML1b.

As shown in FIG. 6, a length of each of the second via plug SV2a, the fourth via plug SV2b, and the sixth via plug SV2c in the first direction X is larger than a length of each of the second via plug SV2a, the fourth via plug SV2b, and the sixth via plug SV2c in the second direction Y. The length of each of the second via plug SV2a, the fourth via plug SV2b, and the sixth via plug SV2c in the second direction Y is equal to or smaller than the length of each of the second lower wiring ML2a, the fourth lower wiring ML2b, and the sixth lower wiring ML2c in the second direction Y. The length of each of the second via plug SV2a, the fourth via plug SV2b, and the sixth via plug SV2c in the second direction Y is equal to or smaller than the length of each of the first upper wiring ML3a, the third upper wiring ML3b, and the fifth upper wiring ML3c in the second direction Y.

As shown in FIG. 6, the shortest distance D4 between the second via plug SV2a and the first upper wiring ML3a is smaller than the shortest distance D5 between the first upper wiring ML3a and the third upper wiring ML3b. The shortest distance D4 between the second via plug SV2a and the first upper wiring ML3a is smaller than half of the shortest distance D5 between the first upper wiring ML3a and the third upper wiring ML3b. The shortest distance D4 between the second via plug SV2a and the first upper wiring ML3a is, for example, equal to the shortest distance between the fourth via plug SV2b and the third upper wiring ML3b.

The shortest distance between the fourth via plug SV2b and the third upper wiring ML3b, the shortest distance between the sixth via plug SV2c and the third upper wiring ML3b, and the shortest distance between the sixth via plug SV2c and the fifth upper wiring ML3c are, for example, equal to the shortest distance D4 between the second via plug SV2a and the first upper wiring ML3a.

The shortest distance D4 between the second via plug SV2a and the first upper wiring ML3a is, for example, equal to the shortest distance DO between the first via plug SV1a and the second lower wiring ML2a.

As shown in FIG. 6, the first lead-out wiring LL is included in the third wiring layers ML3. The first lead-out wiring LL is connected to one end of each of the first upper wiring ML3a, the third upper wiring ML3b, and the fifth upper wiring ML3c in the first direction X, for example. The first lead out wiring LL extends, for example, along the second direction Y. A length of the first lead-out wiring LL in the first direction X is smaller than a length of the first lead-out wiring LL in the second direction Y.

As shown in FIG. 7, s length of each of the second upper wiring ML4a, the fourth upper wiring ML4b, and the sixth upper wiring ML4c in the first direction X is larger than a length of each of the second upper wiring ML4a, the fourth upper wiring ML4b, and the sixth upper wiring ML4c in the second direction Y. The lengths of the second upper wiring ML4a, the fourth upper wiring ML4b, and the sixth upper wiring ML4c in the first direction X are, for example, equal to each other. The arrangement of the second upper wiring ML4a, the fourth upper wiring ML4b and the sixth upper wiring ML4c in the second direction Y is, for example, periodic. The shortest distance D6 between the second upper wiring ML4a and the fourth upper wiring ML4b is equal to the shortest distance between the fourth upper wiring ML4b and the sixth upper wiring ML4c, for example. The shortest distance D6 between the second upper wiring ML4a and the fourth upper wiring ML4b is, for example, the smallest distance between wirings included in the fourth wiring layers ML4.

As shown in FIG. 7, a second lead-out wiring HL is included in the fourth wiring layers ML4. The second lead-out wiring HL is connected to one end of each of the second upper wiring ML4a, the fourth upper wiring ML4b, and the sixth upper wiring ML4c in the first direction X, for example. The second lead-out wiring HL is arranged so as not to overlap with the first lead-out wiring LL in plan view, for example. The second lead-out wiring HL and the first lead-out wiring LL are arranged so as to sandwich the plurality of first electrodes LE1,LE2,LE3, and the plurality of second electrodes HE1,HE2,HE3 in the first direction X, for example, in plan view. The second lead-out wiring HL extends, for example, along the second direction Y. The length of the second lead-out wiring HL in the first direction X is smaller than the length of the second lead-out wiring HL in the second direction Y.

Manufacturing Method of Semiconductor Device

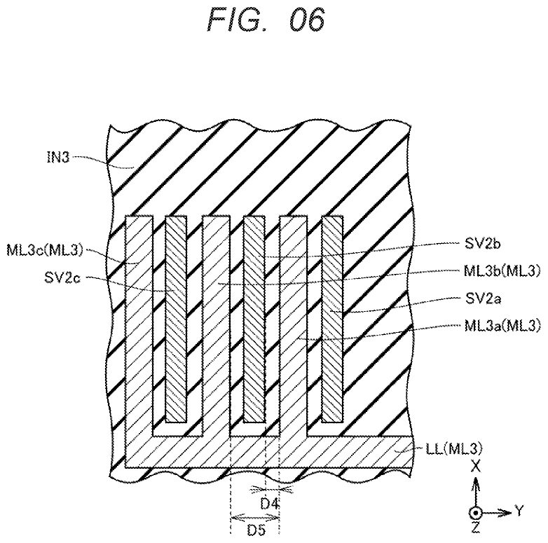

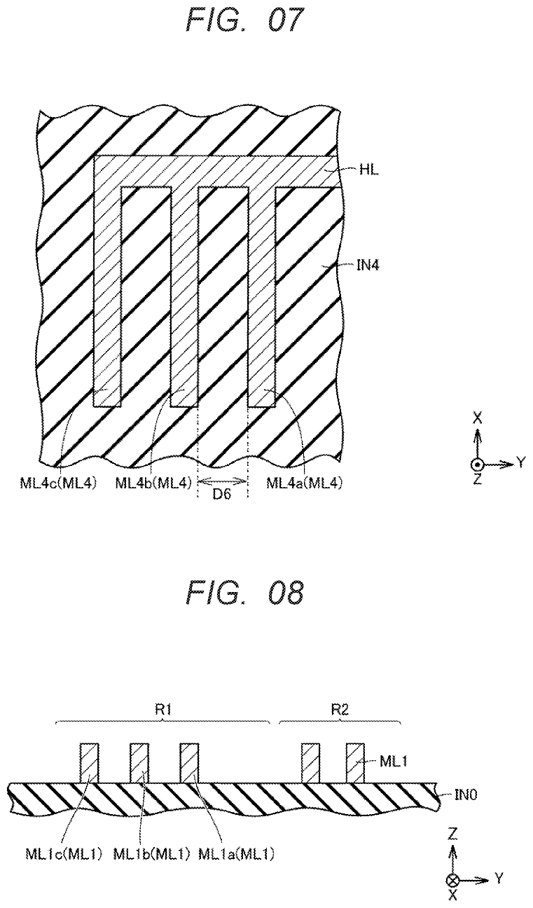

Next, referring to FIGS. 8 to 14, the manufacturing method of semiconductor device SD according to the present embodiment will be described. In the manufacturing method of semiconductor device SD, the MIM capacitor MM1 is formed on the semiconductor substrate SB together with other wiring structures included in the analog circuit AC and the like. In FIGS. 8 to 14, an illustration of semiconductor substrate SB is omitted. In addition, in FIGS. 8 to 14, a region in which the MIM capacitor MM1 is formed (hereinafter, referred to as a first region) is represented as R1, and a region in which another wiring structure is formed (hereinafter, referred to as a second region) is represented as R2.

First, the semiconductor substrate in which the interlayer dielectric film IN0 is formed on the main surface is prepared. The interlayer dielectric film IN0 is formed on the first region R1 and the second region R2. Although not shown, an optional element structure (for example, a transistor) included in the semiconductor device SD may be formed below the interlayer dielectric film IN0 of the semiconductor substrate prepared in this step. A method of forming such a semiconductor substrate may be performed by a conventionally known method, and therefore will not be described here.

Second, as shown in FIG. 8, the first wiring layers ML1 are formed on the interlayer dielectric film IN0. The first wiring layers ML1 include the first lower wiring ML1a, the third lower wiring ML1b, and the fifth lower wiring ML1c in the first region R1. A method of forming the first wiring layers ML1 is not particularly limited. For example, after the conductive film is formed on the interlayer dielectric film IN0 by a sputtering method or the like, the conductive film is patterned by a photolithography method and a dry etching method, or the like. As a result, the first wiring layers ML1 shown in FIG. 8 are formed. As described above, the shortest distance D3 between the first lower wiring ML1a and the third lower wiring ML1b (refer to FIG. 4) may be equal to the smallest distance of the line-and-space pattern defined in design standard of semiconductor device SD.

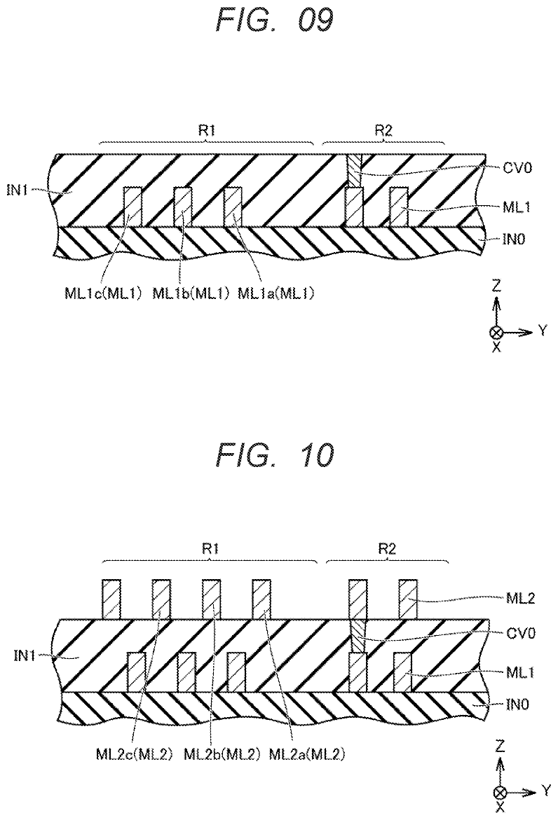

Third, as shown in FIG. 9, the first interlayer dielectric film IN1 is formed on the interlayer dielectric film IN0 and the first wiring layers ML1. A method of forming the first interlayer dielectric film IN1 is not particularly limited, but is, for example, a CVD method. Further, in the second region R2, the contact via plugs CV0 may be formed in the first interlayer dielectric film IN1. The contact via plugs CV0 are electrically connected to the first wiring layers ML1. A method of forming the contact via plugs CV0 is not particularly limited. For example, contact holes are formed in the first interlayer dielectric film IN1 by etching using a resist pattern formed by photolithography as a mask. Thereafter, a conductive film is formed by CVD method or the like so as to fill the contact holes. Thereafter, each part of the first interlayer dielectric film IN1 and the conductive film is partially removed by chemical mechanical polishing (CMP) or the like. In this manner, the contact via plugs CV0 and the first interlayer dielectric film IN1 are formed.

Fourth, as shown in FIG. 10, the second wiring layers ML2 are formed on the first interlayer dielectric film IN1. The second wiring layers ML2 include the second lower wiring ML2a, the fourth lower wiring ML2b, and the sixth lower wiring ML2c in the first region R1. The second lower wiring ML2a, the fourth lower wiring ML2b, and the sixth lower wiring ML2c are formed so as not to overlap with each of the first lower wiring ML1a, the third lower wiring ML1b, and the fifth lower wiring ML1c in plan view. The second wiring layers ML2 include a portion electrically connected to the contact via plug CV0 in the second region R2.

As described above, the shortest distance D1 between the second lower wiring ML2a and the first lower wiring ML1a in the second direction Y is smaller than the shortest distance D2 between the second lower wiring ML2b and the fourth lower wiring ML2b.

A method of forming the second wiring layers ML2 is not particularly limited. For example, a conductive film is formed on the first interlayer dielectric film IN1 by a sputtering method or the like, and thereafter, a mask pattern is formed on the conductive film by photolithography or the like, and then a part of the conductive film exposed from the mask pattern is partially removed. In photolithography, a resist pattern aligned with the first wiring layers ML1 is formed using an alignment mark (not shown).

Fifth, as shown in FIG. 11, the second interlayer dielectric film IN2 is formed on the first interlayer dielectric film IN1 and the second wiring layers ML2. Further, in the first region R1, the plurality of via plugs SV1 are formed so as to penetrate the second interlayer dielectric film IN2 and reach the first wiring layers ML1.

A method of forming the plurality of via plugs SV1 is not particularly limited. For example, a plurality of through holes penetrating the second interlayer dielectric film IN2 and reaching the first wiring layers ML1 are formed. Each of the through holes may be formed by etching using a resist pattern formed using photolithography as a mask. In photolithography, a resist pattern aligned with the first wiring layers ML1 is formed using an alignment mark (not shown). Thereafter, a conductive film is formed by a CVD method or the like so as to fill each of the plurality of through holes. Thereafter, each part of the second interlayer dielectric film IN2 and the conductive film is partially removed by chemical mechanical polishing (CMP) or the like. In this manner, the plurality of via plugs SV1 and the second interlayer dielectric film IN2 are formed.

In this step, the plurality of contact via plugs CV1 may be formed in the second region R2 so as to penetrate the second interlayer dielectric film IN2 and reach the first wiring layers ML1. The plurality of via plugs SV1 and the contact via plugs CV1 may be formed simultaneously.

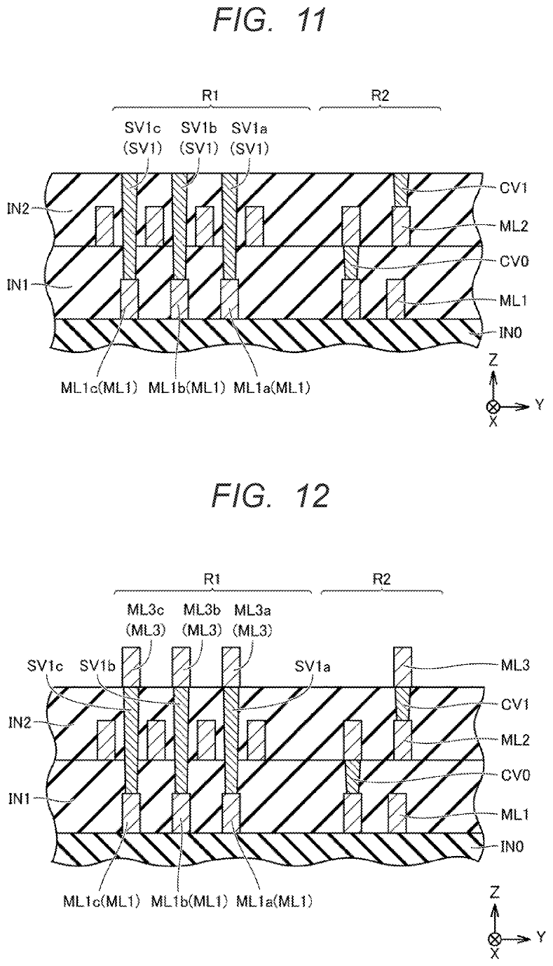

Sixth, as shown in FIG. 12, the third wiring layers ML3 are formed on the second interlayer dielectric film IN2. The third wiring layers ML3 include the first upper wiring ML3a, the third upper wiring ML3b, and the fifth upper wiring ML3c in the first region R1. The first upper wiring ML3a, the third upper wiring ML3b, and the fifth upper wiring ML3c are formed so as to overlap with each of the first via plug SV1a, the third via plug SV1b, and the fifth via plug SV1c in plan view. The third wiring layers ML3 include a portion electrically connected to the contact via plug CV1 in the second region R2.

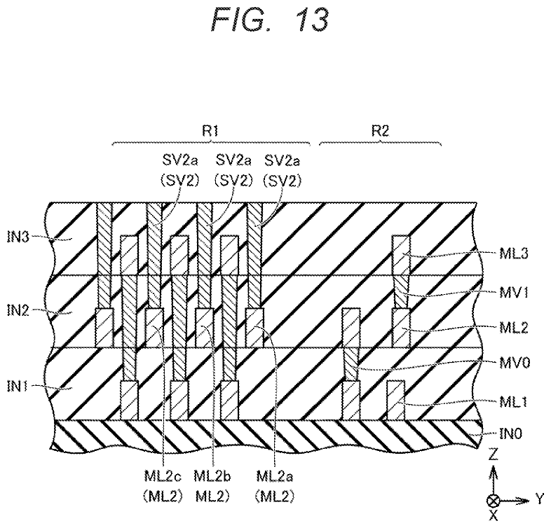

Seventh, as shown in FIG. 13, the third interlayer dielectric film IN3 is formed on the second interlayer dielectric film IN2 and the third wiring layers ML3. Further, in the first region R1, the plurality of via plugs SV2 are formed so as to penetrate the third interlayer dielectric film IN3 and reach the second wiring layers ML2.

A method of forming the plurality of via plugs SV2 is not particularly limited, but is the same as the method of forming the plurality of via plugs SV1, for example. For example, a plurality of through holes penetrating the third interlayer dielectric film IN3 and reaching the second wiring layers ML2 are formed. Each of the through holes may be formed by etching using a resist pattern formed using photolithography as a mask. In photolithography, a resist pattern aligned with the second wiring layers ML2 is formed using an alignment mark (not shown). Thereafter, a conductive film is formed by a CVD method or the like so as to fill each of the plurality of through holes. Thereafter, each part of the third interlayer dielectric film IN3 and the conductive film is removed by CMP or the like. In this manner, the plurality of via plugs SV2 and the third interlayer dielectric film IN3 shown in FIG. 13 are formed.

Also in this step, a plurality of contact via plugs may be formed in the second region R2.

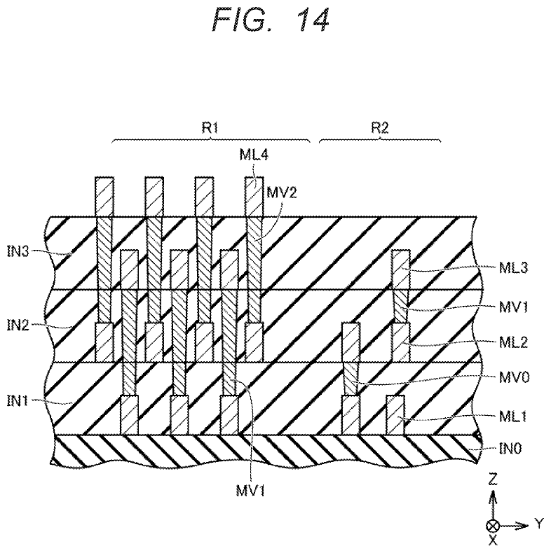

Eighth, as shown in FIG. 14, the fourth wiring layers ML4 are formed on the third interlayer dielectric film IN3. The fourth wiring layers ML4 include the second upper wiring ML4a, the fourth upper wiring ML4b, and the sixth upper wiring ML4c in the first region R1. The second upper wiring ML4a, the fourth upper wiring ML4b, and the sixth upper wiring ML4c are formed so as to overlap with each of the second via plug SV2a, the fourth via plug SV2b, and the sixth via plug SV2c in plan view. Ninth, the fourth interlayer dielectric film IN4 is formed on the third interlayer dielectric film IN3 and the fourth wiring layers ML4.

In this way, the MIM capacitor MM1 shown in FIG. 3 is formed. After this step, an optional structure included in the semiconductor device SD may be formed above the fourth interlayer dielectric film IN4. A method of forming such a structure may be performed by a conventionally known method, and therefore, description thereof will be omitted here. Thus, the semiconductor device SD is manufactured.

Effects of Semiconductor Device

The effects of semiconductor device SD will be described based on the comparison with the comparative example. The first electrode and the second electrode of MIM capacitor of semiconductor device according to the comparative example are configured by only a plurality of wirings included in the same wiring layers. Therefore, as described above, the capacitance value of MIM capacitor of the comparative example is limited by the minimum interval and the aspect ratio defined in the design standard for wiring pattern formed from one conductive film from the viewpoint of suppressing the generation of processing defects. From a different point of view, the miniaturization of MIM capacitor of the comparative example is limited by the smallest interval between wirings included in one wiring layer and aspect ratio.

Specifically, the capacitance value of MIM capacitor of the comparative example is determined by the interval between a wiring configuring the first electrode and a wiring configuring the second electrode, the area of the opposing regions in both wirings (hereinafter, referred to as the facing area), and the dielectric constant of the dielectric film located between the first electrode and the second electrode. In the MIM capacitor of the comparative example, the interval between wiring configuring the first electrode and wiring configuring the second electrode is limited to be equal to or more than the minimum interval defined in the design standard for wiring pattern formed from one conductive film. In the MIM capacitor of the comparative example, the aspect ratio (thickness/width) of the respective wiring patterns is limited to be equal to or less than the aspect ratio defined in the design standard for wiring patterns formed from one conductive film. Therefore, in the case where the interval is reduced, it is necessary to reduce the facing area, and as a result, it is difficult to increase the capacitance value.

On the other hand, the first electrode LE of MIM capacitor MM1 of semiconductor device SD includes a first via plug SV1a that is a slit via, and the second electrode HE includes a second lower wiring ML2a that is arranged side by side with the first via plug SV1a in the second direction Y. The length of the first via plug SV1a in the third direction Z is larger than the length (thickness) of the second lower wiring ML2a in the third direction Z. Since the first via plug SV1a and the second lower wiring ML2a are not formed from one conductive film, the shortest distance DO between the first via plug SV1a and the second lower wiring ML2a and the length of the first via plug SV1a in the third direction Z are not limited by the smallest interval and aspect ratio defined in the design standard for wiring pattern formed from one conductive film. Therefore, in the MIM capacitor MM1 of semiconductor device SD, it is possible to reduce the shortest distance DO without reducing the facing area between the first via plug SV1a and the second lower wiring ML2a. The shortest distance DO may be reduced than the smallest distance between wirings of the second wiring layers ML2 in which the second lower wiring ML2a is included. Consequently, the capacitance value of MIM capacitor MM1 of semiconductor device SD may be larger than that of MIM capacitor of the comparative example.

In the semiconductor device SD, the second electrode HE further includes a second via plug SV2a extending from the second lower wiring ML2a in the third direction Z and arranged side by side with a part of the first via plug SV1a in the second direction Y. In this case, the facing area between the first electrode LE and the second electrode HE is larger than that in the case where the second electrode HE does not include the second via plug SV2a by the facing area between the first via plug SV1a and the second via plug SV2a. As a consequence, the capacitance value of MIM capacitor MM1 of semiconductor device SD may be larger than that of MIM capacitor of the comparative example.

For example, the MIM capacitor MM1 shown in FIG. 3 is compared with MIM capacitor of the comparative example. When the occupied areas of the two in plan view are equal to each other, the capacitance value of MIM capacitor shown in FIG. 3 may be twice as large as the capacitance value of MIM capacitor of the comparative example. In addition, when the capacitance values of the two capacitors are equal to each other, the occupied area of MIM capacitor shown in FIG. 3 in plan view can be reduced to 57% of the occupied area of MIM capacitor in plan view of the comparative example.

Further, the MIM capacitor MM1 shown in FIG. 3 is compared with the MIM capacitor of the comparative example shown in FIG. 15. In the comparative example shown in FIG. 15, a first wiring layers ML11 to a fourth wiring layers ML14 are stacked at an interval D7 from each other in the third direction Z, and each wiring layers includes a plurality of wirings arranged side by side in the second direction Y at an interval D8. The interval D7 is defined to be equal to the interval between the first wiring layers ML1 and the third wiring layers ML3 and the interval between the second wiring layers ML2 and the fourth wiring layers ML4 in FIG. 3. The interval M8 is defined to be equal to each of the shortest distance D2 shown in FIG. 3, the shortest distance D3 shown in FIG. 4, the shortest distance D5 shown in FIG. 6, and the shortest distance D6 shown in FIG. 7. In this case, in the MIM capacitor MM1 shown in FIG. 3, compared with the MIM capacitor shown in FIG. 15, the capacitance value is 1.5 times, and the occupied area in plan view is 0.8 times. That is, in contrast to the MIM capacitor shown in FIG. 15, the MIM capacitor MM1 shown in FIG. 3 can achieve both an increase in capacitance value and a miniaturization in capacitor.

In the manufacturing method of semiconductor device SD including the MIM capacitor MM1, as described above, since the second lower wiring ML2a and the first via plug SV1a are formed in separate steps, the shortest distance DO between the first via plug SV1a and the second lower wiring ML2a can be set to be approximately the same as the alignment error (alignment accuracy) of the photolithography. Since the alignment error (alignment accuracy) at a typical exposure apparatus used in photolithography can be made smaller than the smallest interval of the line-and-space, the shortest distance DO and the shortest distance D1 can be made smaller than the minimum interval of the line-and-space. Therefore, the semiconductor device SD can be manufactured relatively easily by separately forming the first via plug SV1a and the second lower wiring ML2a based on known manufacturing processes.

### Second Embodiment

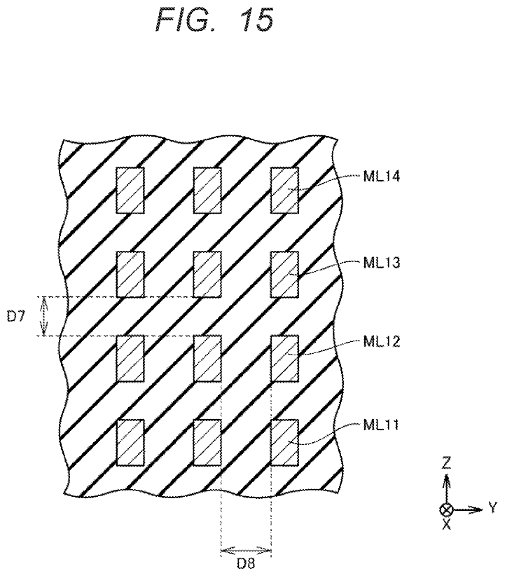

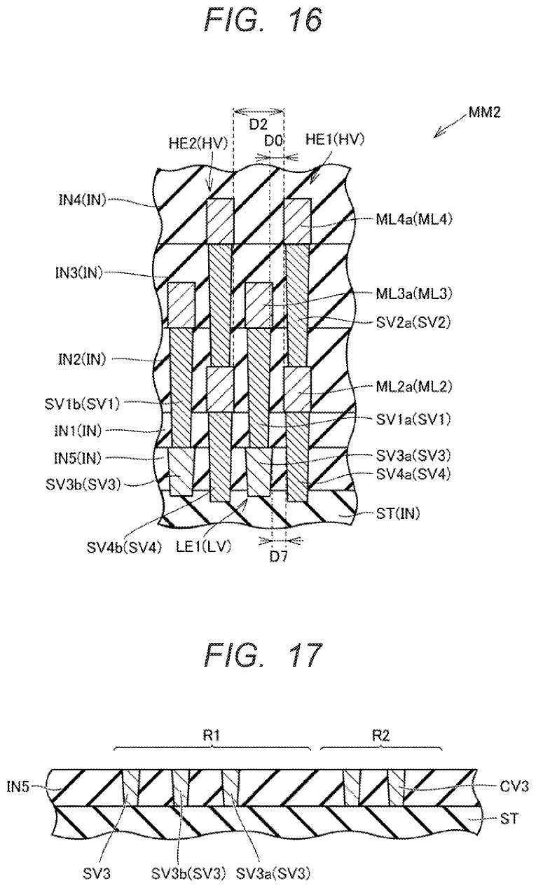

The semiconductor device according to the second embodiment shown in FIG. 16 has basically the same configuration as the semiconductor device SD according to the first embodiment, but differs from the semiconductor device SD in that it has a MIM capacitor MM2 instead of a MIM capacitor MM1. The MIM capacitor MM2 has basically the same configuration as MIM capacitor MM1, but differs from the MIM capacitor MM1 in that it includes an etching stopper film ST instead of the interlayer dielectric film IN0, includes a plurality of via plugs SV3 instead of the first wiring layers ML1, and further includes a plurality of via plugs SV4. In the following, the differences between the MIM capacitor MM2 and the MIM capacitor MM1 will be mainly described.

As shown in FIG. 16, the dielectric film IN of MIM capacitor MM2 includes, for example, an etching stopper film ST, a fifth interlayer dielectric film IN5, a first interlayer dielectric film IN1, a second interlayer dielectric film IN2, a third interlayer dielectric film IN3, and a fourth interlayer dielectric film IN4, which are sequentially stacked in the third direction Z. A structure above the second interlayer dielectric film IN2 in the MIM capacitor MM2 is the same as that in the MIM capacitor MM1.

The material configuring the etching stopper film ST is a material having a lower etching rate for forming via holes in the fifth interlayer dielectric film IN5 in the plurality of via plugs SV3 forming step than the material configuring the fifth interlayer dielectric film IN5. A material configuring the etching stopper film ST includes, for example, silicon oxynitride (SiON). The fifth interlayer dielectric film IN5 is formed on the etching stopper film ST. A material configuring the fifth interlayer dielectric film IN5 includes, for example, SiO₂.

The plurality of via plugs SV3 are included in the first electrode LE of MIM capacitor MM2. Each of the plurality of via plugs SV3 is arranged at a lowermost position in the first electrode LE. Each of the plurality of via plugs SV3 penetrates the fifth interlayer dielectric film IN5 and reaches the etching stopper film ST. A lower end part of each of the plurality of via plugs SV3 is in contact with the etching stopper film ST.

A length of each of the plurality of via plugs SV3 in the first direction X is larger than a length of each of the plurality of via plugs SV3 in the second direction Y. A length of each of the plurality of via plugs SV3 in the third direction Z is smaller than a length of each of the first via plug SV1a and the second via plug SV2a in the third direction Z, for example.

The plurality of via plugs SV3 include a seventh via plug SV3a connected to a lower end part of the first via plug SV1a, and an eighth via plug SV3b connected to a lower end part of the third via plug SV1b.

The plurality of via plugs SV4 are included in the second electrode HE of MIM capacitor MM2. Each of the plurality of via plugs SV4 is arranged at a lowermost position in the second electrode HE. Each of the plurality of via plugs SV4 penetrates the first interlayer dielectric film IN1 and the fifth interlayer dielectric film IN5 and reaches the etching stopper film ST. A lower end part of each of the plurality of via plugs SV4 is in contact with the etching stopper film ST.

A length of each of the plurality of via plugs SV4 in the first direction X is larger than a length of each of the plurality of via plugs SV4 in the second direction Y. A length of each of the plurality of via plugs SV4 in the third direction Z is larger than a length of each of the plurality of via plugs SV3 in the third direction Z.

The plurality of via plugs SV4 include a ninth via plug SV4a connected to the second lower wiring ML2a and a tenth via plug SV4b connected to the fourth lower wiring ML2b. The ninth via plug SV4a is arranged so as to overlap with the second lower wiring ML2a in plan view. The tenth via plug SV4b is arranged so as to overlap with the fourth lower wiring ML2b in plan view. The ninth via plug SV4a, the seventh via plug SV3a, the tenth via plug SV4b, and the eighth via plug SV3b are arranged side by side and spaced apart in the second direction Y. The seventh via plug SV3a and the lower part of the first via plug SV1a faces the ninth via plug SV4a in the second direction Y and faces the tenth via plug SV4b. The shortest distance D7 between the seventh via plug SV3a and the ninth via plug SV4a is smaller than the shortest distance D2. The shortest distance D7 is equivalent to, for example, the shortest distance DO.

The material configuring the plurality of via plugs SV3 and the plurality of via plugs SV4 includes, for example, W.

A manufacturing method of semiconductor device according to the second embodiment has basically the same configuration as the manufacturing method of semiconductor device SD according to the first embodiment, but differs from the manufacturing method of semiconductor device SD according to the first embodiment in that the MIM capacitor MM2 is formed instead of the MIM capacitor MM1. Referring to FIGS. 17 to 21, a step of forming the MIM capacitor MM2 will be described below.

First, a semiconductor substrate in which an etching stopper film ST is formed on the main surface is prepared. The etching stopper film ST is formed on the first region R1 and the second region R2. In the semiconductor substrate prepared in this step, an optional element structure (for example, a transistor) included in the semiconductor device SD may be formed below the etching stopper film ST.

Second, as shown in FIG. 17, a fifth interlayer dielectric film IN5 is formed on the etching stopper film ST. Further, in the first region R1, the plurality of via plugs SV3 are formed so as to penetrate the fifth interlayer dielectric film IN5 and reach the etching stopper film ST.

The method of forming the plurality of via plugs SV3 is not particularly limited, but is the same as the method of forming the plurality of via plugs SV1 described above, for example. A plurality of via holes penetrating the fifth interlayer dielectric film IN5 and reaching the etching stopper film ST are formed. At this time, the bottom surface of the via hole may be formed in the etching stopper film ST because the material configuring the etching stopper film ST is a material having a lower etching rate for forming the via hole than the material configuring the fifth interlayer dielectric film IN5.

In this step, a plurality of contact via plugs CV3 may be formed in the second region R2 so as to penetrate the fifth interlayer dielectric film IN5 and reach the etching stopper film ST. The plurality of via plugs SV3 and the contact via plugs CV3 may be formed simultaneously.

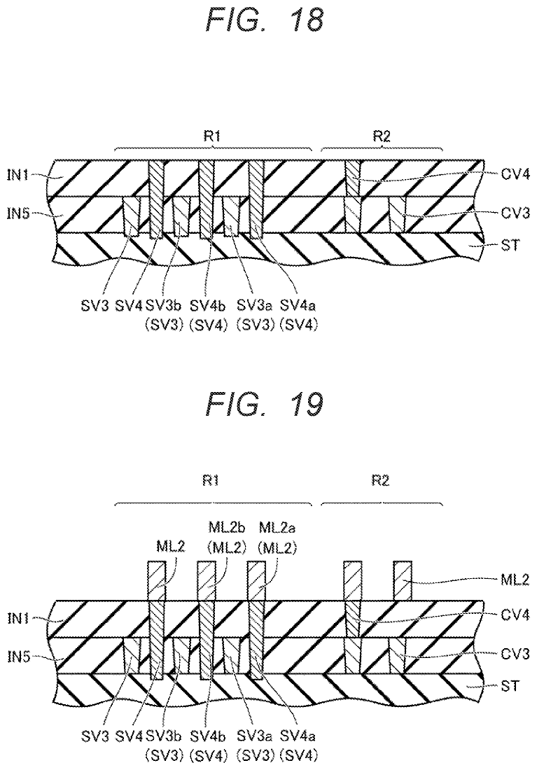

Third, as shown in FIG. 18, the first interlayer dielectric film IN1 is formed on the fifth interlayer dielectric film IN5, the plurality of via plugs SV3, and the contact via plugs CV3. A method of forming the first interlayer dielectric film IN1 is as described above. Further, in the first region R1, the plurality of via plugs SV4 are formed so as to penetrate the first interlayer dielectric film IN1 and the fifth interlayer dielectric film IN5 and reach the etching stopper film ST. The method of forming the plurality of via plugs SV4 is not particularly limited, but is the same as the method of forming the plurality of via plugs SV3, for example.

In this step, a plurality of contact via plugs CV4 may be formed in the second region R2 so as to penetrate the first interlayer dielectric film IN1 and reach the contact via plugs CV3. The plurality of via plugs SV4 and the contact via plugs CV4 may be formed simultaneously.

Fourth, as shown in FIG. 19, the second wiring layers ML2 are formed on the first interlayer dielectric film IN1. The second wiring layers ML2 include a second lower wiring ML2a and a fourth lower wiring ML2b in the first region R1. The second lower wiring ML2a is formed so as to overlap with the ninth via plug SV4a in plan view. The fourth lower wiring ML2b is formed so as to overlap with the tenth via plug SV4b in plan view. The second wiring layers ML2 include a portion electrically connected to the contact via plug CV4 in the second region R2. The method of forming the second wiring layers ML2 is as described above.

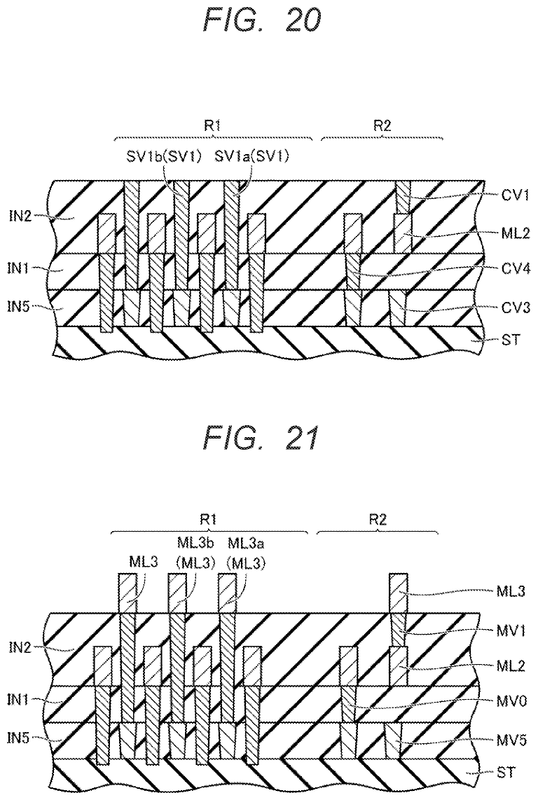

Fifth, as shown in FIG. 20, the second interlayer dielectric film IN2 is formed on the first interlayer dielectric film IN1 and the second wiring layers ML2. Further, in the first region R1, the plurality of via plugs SV1 are formed so as to penetrate the second interlayer dielectric film IN2 and reach the plurality of via plugs SV3. The method of forming the plurality of via plugs SV1 is as described above.

In this step, the plurality of contact via plugs CV1 may be formed in the second region R2 so as to penetrate the second interlayer dielectric film IN2 and reach the second wiring layers ML2. The plurality of via plugs SV1 and the contact via plugs CV1 may be formed simultaneously.

Sixth, as shown in FIG. 21, the third wiring layers ML3 are formed on the second interlayer dielectric film IN2. The method of forming the third wiring layers ML3 is as described above.

After that, the MIM capacitor MM2 according to the second embodiment can be formed by performing the same process as that shown in FIGS. 13 and 14.

The semiconductor device according to the second embodiment has basically the same configuration as that of semiconductor device SD according to the first embodiment, and thus has the same effects as semiconductor device SD according to the first embodiment. Furthermore, in the MIM capacitor MM2 of semiconductor device according to the second embodiment, a part of the ninth via plug SV4a extending downward from the second lower wiring ML2a faces the lower part of the first via plug SV1a in the second direction Y, and the other part of the ninth via plug SV4a faces the seventh via plug SV3a in the second direction Y. Therefore, in the MIM capacitor MM2, the facing area between the first electrode LE and the second electrode HE is larger than the facing area between the first electrode LE and the second electrode HE in the MIM capacitor MM1. As a consequence, in the MIM capacitor MM2, an increase in capacitance value and a miniaturization of capacitor can be achieved at a higher level than in the MIM capacitor MM1.

For example, the MIM capacitor MM2 shown in FIG. 16 is compared with that of the comparative example shown in FIG. 15. In the comparative example shown in FIG. 15, the first wiring layers ML11 to the fourth wiring layers ML14 are stacked at an interval D7 from each other in the third direction Z, and each wiring layers includes a plurality of wiring layers arranged side by side and spaced apart in the second direction Y at an interval D8. The interval D7 is defined to be equal to the interval between the plurality of via plugs SV3 and the third wiring layers ML3 and the interval between the second wiring layers ML2 and the fourth wiring layers ML4 in FIG. 16. The interval D8 is defined to be equal to the shortest distance D2 shown in FIG. 16. In this case, in the MIM capacitor MM2 shown in FIG. 16, compared with the MIM capacitor shown in FIG. 15, the capacitance value is 2.5 times, and the occupied area in plan view is 0.8 times.

Modification

Note that the MIM capacitors MM1,MM2 may be configured by at least one first electrode LE, at least one second electrode HE, and a dielectric film. In the MIM capacitors MM1,MM2, at least one of the first electrode LE and the second electrode HE may include at least one via plug SV, and at least the other of the first electrode LE and the second electrode HE may include at least one wiring ML. At least one of the first electrode LE and the second electrode HE may be configured by one via plug SV, and at least the other of the first electrode LE and the second electrode HE may be configured by one wiring ML.

Although the invention made by the present inventor has been specifically described based on the embodiment, the present invention is not limited to the embodiment described above, and it is needless to say that various modifications can be made without departing from the gist thereof.

What is claimed is:

1. A semiconductor device comprising:
a first electrode and a second electrode configuring a capacitor,
wherein the first electrode includes a first via plug extending along a first direction in plan view,
wherein the second electrode includes a first wiring extending along the first direction in plan view and arranged side by side with the first via plug in a second direction orthogonal to the first direction,
wherein a length of the first via plug in the first direction is larger than a length of the first via plug in the second direction,
wherein a length of the first wiring in the first direction is larger than a length of the first wiring in the second direction, and
wherein a thickness of the first via plug in a third direction orthogonal to each of the first direction and the second direction is larger than a thickness of the first wiring in the third direction.

2. The semiconductor device according to claim 1, comprising:
a first dielectric layer arranged on the first wiring,
wherein the first via plug penetrates the first dielectric layer.

3. The semiconductor device according to claim 2, comprising:
a second dielectric layer arranged on the first dielectric layer; and
a second via plug extending along the third direction from an upper surface of the first wiring and arranged side by side with at least part of the first via plug in the second direction,
wherein the second via plug penetrates the second dielectric layer.

4. The semiconductor device according to claim 1,
wherein the second electrode includes a second wiring extending along the first direction and arranged side by side with the first via plug in the second direction, and
wherein the first wiring and the second wiring are arranged so as to sandwich the first via plug.

5. The semiconductor device according to claim 4,
wherein a potential of the first wiring is equal to a potential of the second wiring.

6. The semiconductor device according to claim 1, comprising:
a third wiring and a fourth wiring arranged spaced apart from each other in the third direction, the third wiring and the fourth wiring each extending along the first direction,
wherein the first via plug electrically connects between the third wiring and the fourth wiring.

7. The semiconductor device according to claim 1, comprising:
an etching stopper film in contact with one end of the first via plug in the third direction.

8. The semiconductor device according to claim 1,
wherein the length of the first via plug in the first direction is larger than the length of the first wiring in the second direction.

9. A method of manufacturing a semiconductor device having a capacitor, the method comprising:
preparing a substrate having a first surface extending along a first direction and a second direction orthogonal to the first direction;
forming a first wiring of which a length in the first direction is larger than a length of the first wiring in the second direction, on the first surface as a first electrode;
forming a first dielectric layer on the first wiring; and
forming a first via plug arranged side by side with the first wiring in the second direction as a second electrode configuring the capacitor with the first electrode,
wherein in the forming the first via plug, the first via plug is formed so as to penetrate the first dielectric layer.

10. The method according to claim 9,
wherein in the forming the first wiring, the first wiring and the second wiring arranged spaced apart from the first wiring in the second direction are formed from one conductive film, and
wherein in the forming the first via plug, the first via plug is formed between the first wiring and the second wiring.
